(19) United States
(12) Patent Application Publication
(10) Pub. No.: US 2010/0271074 A1
(43) Pub. Date: Oct. 28, 2010

(54) COMPARISON CIRCUIT, INTEGRATED CIRCUIT DEVICE AND ELECTRONIC APPARATUS

(75) Inventor: Noriyuki MURASHIMA, Suwa-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/723,970

(22) Filed: Mar. 15, 2010

(30) Foreign Application Priority Data
Apr. 28, 2009 (JP) 2009-108981

(51) Int. Cl. H03L 5/00

(52) U.S. Cl. 327/60

(57) ABSTRACT

A comparison circuit includes a comparator into a first input terminal of which an input signal is input, and into a second input terminal of which a reference voltage for comparison is input, a controller which monitors an output signal of the comparator, and a voltage generation circuit into which a threshold voltage control signal from the controller is input, wherein the voltage generation circuit, when the voltage level of the output signal of the comparator is a first level, outputs as the reference voltage a first threshold voltage which is one of a high potential side threshold voltage and a low potential side threshold voltage which define a hysteresis width, and when the voltage level of the output signal of the comparator is a second level, outputs as the reference voltage a second threshold voltage which is the other one of the high potential side threshold voltage and low potential side threshold voltage.

The present application, claiming priority based on Japanese Patent Application No. 2009-108981 filed as of Apr. 28, 2009, is incorporated in the specification.

### TECHNICAL FIELD

An aspect of the present invention relates to a comparison circuit, an integrated circuit device, an electronic apparatus.

### BACKGROUND ART

In recent years, a sensor network has attracted attention wherein, with a plurality of sensors connected via a network, a situation is comprehensively determined by acquiring information from each of the sensors. With this kind of sensor network, various sensors are used, such as a temperature sensor, a smoke sensor, an optical sensor, a human presence sensor, a pressure sensor, a living organism sensor, and a gyro sensor.

However, as detection signals (sensor signals) of the sensors are analog signals, in order to carry out processes of analyzing and determining the information by means of a CPU or the like, it is necessary to amplify the analog signals, and convert them into digital data by means of an A/D conversion circuit. This requires that the sensor signals be amplified to an appropriate input level of the A/D conversion circuit.

A comparison circuit with hysteresis characteristics is used to determine whether or not an input signal is at the appropriate level, but it is necessary to set a hysteresis width to an optimum value in accordance with the situation of the input signal level, a noise level, or the like.

With respect to this problem, for example, a technique of changing a current mirror ratio of a current mirror circuit included in the comparison circuit is disclosed in Patent Document 1. Also, a technique of changing a gate length or gate width of a transistor included in the comparison circuit is disclosed in Patent Document 2.

However, with these techniques, there has been a problem in that it is difficult to set the hysteresis width to the optimum value in accordance with the status of the input signal level, noise level, or the like.

### PRIOR ART DOCUMENTS

### Patent Documents

[Patent Document 1] JP-A-2003-008409

[Patent Document 2] JP-A-2008-005547

### GENERAL DESCRIPTION OF THE INVENTION

### Problems that the Invention is to Solve

According to some aspects of the invention, it is possible to provide a comparison circuit, which can set a hysteresis width, an integrated circuit device, an electronic apparatus, and the like.

### Means for Solving the Problems

One aspect of the invention relates to a comparison circuit characterized by including a comparator into a first input terminal of which an input signal is input, and into a second input terminal of which a reference voltage for comparison is input, a controller which monitors an output signal of the comparator, and a voltage generation circuit into which a threshold voltage control signal from the controller is input, wherein the voltage generation circuit, when the voltage level of the output signal of the comparator is a first level, outputs as the reference voltage a first threshold voltage which is one of a high potential side threshold voltage and a low potential side threshold voltage which define a hysteresis width, and when the voltage level of the output signal of the comparator is a second level, outputs as the reference voltage a second threshold voltage which is the other one of the high potential side threshold voltage and low potential side threshold voltage.

According to the aspect of the invention, it is possible to determine whether the voltage level of the input signal is higher or lower than the reference voltage for comparison. Also, as the comparison circuit has hysteresis characteristics, when the input signal includes noise, it is possible to prevent malfunction due to the noise. Also, as it is possible to provide the hysteresis characteristics without using a positive feedback, it is possible to prevent an effect of a feedback current on the preceding circuit.

Also, with the aspect of the invention, it is also acceptable that the voltage generation circuit includes a first resistance circuit to third resistance circuit provided in series between a first power source node and a second power source node, and that the resistance value of each of the first resistance circuit and third resistance circuit is set based on the threshold voltage control signal from the controller.

By so doing, the reference voltage for comparison can be set based on the threshold voltage control signal, meaning that it is possible to set the threshold voltage and hysteresis width to desired values.

Also, with the aspect of the invention, it is also acceptable that the first resistance circuit includes a first resistance element to mth resistance element (m is an integer of two or more) and a first bypass switch to mth bypass switch provided corresponding to the first resistance element to mth resistance element, the third resistance circuit includes an m+1th resistance element to nth resistance element (n is an integer wherein n≧m+2) and an m+1th bypass switch to nth bypass switch provided corresponding to the m+1th resistance element to nth resistance element, and the first bypass switch to mth bypass switch and m+1th bypass switch to nth bypass switch are on and off controlled by the threshold voltage control signal.

By so doing, it is possible to change the hysteresis width by turning on and off the bypass switches based on the threshold voltage control signal.

Also, with the aspect of the invention, it is also acceptable that when the voltage level of the output signal of the comparator is the first level, the first bypass switch to mth bypass switch of the first resistance circuit come into an on condition, and the m+1th bypass switch to nth bypass switch of the third resistance circuit come into an off condition, and when the voltage level of the output signal of the comparator is the second level, at least one of the first bypass switch to mth bypass switch of the first resistance circuit comes into the off condition, and at least one of the m+1th bypass switch to nth bypass switch of the third resistance circuit comes into the on condition.

By so doing, it is possible to gradually change the hysteresis width by turning on and off the bypass switches, meaning that it is possible to set an optimum hysteresis width in accordance with an input signal level, a noise level, or the like.

Also, with the aspect of the invention, it is also acceptable that a first sum value which is the sum of the resistance values of the first resistance element to mth resistance element is equal to a second sum value which is the sum of the resistance values of the m+1th resistance element to nth resistance element, and the first sum value is equal to a third sum value which is the sum of the resistance values of resistance elements, among the first resistance element to mth resistance element and m+1th resistance element to nth resistance element, which are non-bypassed when the voltage level of the output signal of the comparator is the second level.

By so doing, even in the event that a threshold voltage setting is changed, the hysteresis width is maintained constant, and furthermore, hysteresis width setting increments (steps) are also maintained constant. As a result, it is possible to realize a level determination circuit which can flexibly respond to conditions of the input signal level, noise level, or the like.

Also, with the aspect of the invention, it is also acceptable that the voltage generation circuit includes a selector, and the selector selects one voltage division node among a plurality of voltage division nodes of the second resistance circuit, and outputs the reference voltage.

By so doing, it is possible, by selecting a voltage division node, to select an optimum reference voltage, that is, the threshold voltage. As a result, it is possible to realize the level determination circuit which can flexibly respond to the conditions of the input signal level or the like.

Another aspect of the invention relates to a comparison circuit characterized by including a first comparator into a first input terminal of which an input signal is input, and into a second input terminal of which a first reference voltage for comparison is input; a second comparator into a first input terminal of which a second reference voltage for comparison is input, and into a second input terminal of which the input signal is input; a controller which monitors a first output signal which is an output signal of the first comparator, and a second output signal which is an output signal of the second comparator; a first voltage generation circuit into which a first threshold voltage control signal from the controller is input; and a second voltage generation circuit into which a second threshold voltage control signal from the controller is input, wherein the first voltage generation circuit, when the voltage level of the first output signal is a first level, outputs as the first reference voltage a first high potential side threshold voltage which defines a first hysteresis width, and when the voltage level of the first output signal is a second level, outputs as the first reference voltage a first low potential side threshold voltage which defines the first hysteresis width, and the second voltage generation circuit, when the voltage level of the second output signal is the first level, outputs as the second reference voltage a second low potential side threshold voltage which defines a second hysteresis width, and when the voltage level of the second output signal is the second level, outputs as the second reference voltage a second high potential side threshold voltage which defines the second hysteresis width.

According to the other aspect of the invention, it is possible to determine whether or not the voltage level of the input signal is within two preset voltage level ranges. Also, as it is possible to provide the hysteresis characteristics without using the positive feedback, it is possible to prevent the effect of the feedback current on the preceding circuit.

Also, with the other aspect of the invention, it is also acceptable that the first voltage generation circuit includes a first resistance circuit to third resistance circuit provided in series between a first power source node and a second power source node, the second voltage generation circuit includes a fourth resistance circuit to sixth resistance circuit provided in series between the first power source node and second power source node, the resistance value of each of the first resistance circuit and third resistance circuit is set based on the first threshold voltage control signal from the controller, and the resistance value of each of the fourth resistance circuit and sixth resistance circuit is set based on the second threshold voltage control signal from the controller.

By so doing, the reference voltages for comparison can be set based on the threshold voltage control signals, meaning that it is possible to set the first and second threshold voltages, and the hysteresis width of each of them, to desired values.

Also, with the other aspect of the invention, it is also acceptable that the first resistance circuit includes a first resistance element to mth resistance element (m is an integer of two or more) and a first bypass switch to mth bypass switch provided corresponding to the first resistance element to mth resistance element, the third resistance circuit includes an m+1th resistance element to nth resistance element (n is an integer wherein n≧m+2) and an m+1th bypass switch to nth bypass switch provided corresponding to the m+1th resistance element to nth resistance element, and the first bypass switch to mth bypass switch and m+1th bypass switch to nth bypass switch are on and off controlled by the first threshold voltage control signal, and that the fourth resistance circuit includes an n+1th resistance element to n+pth resistance element (p is an integer of two or more) and an n+1th bypass switch to n+pth bypass switch provided corresponding to the n+1th resistance element to n+pth resistance element, the sixth resistance circuit includes an n+p+1th resistance element to n+qth resistance element (q is an integer wherein q≧p+2) and an n+p+1th bypass switch to n+qth bypass switch provided corresponding to the n+p+1th resistance element to n₊qth resistance element, and the n₊1th bypass switch to n₊pth bypass switch and n+p+1th bypass switch to n+qth bypass switch are on and off controlled by the second threshold voltage control signal.

By so doing, it is possible to gradually change the hysteresis width by turning on and off the bypass switches, meaning that it is possible to set the optimum hysteresis width in accordance with the input signal level, noise level, or the like.

Another aspect of the invention relates to an integrated circuit device and electronic apparatus characterized by including the heretofore described comparison circuit.

### BRIEF DESCRIPTION OF THE DRAWINGS

FIG. 1 shows a first basic configuration example of a comparison circuit.

FIG. 2(A) and FIG. 2(B) are illustrations of operations of a comparator.

FIG. 3 shows a first detailed configuration example of the comparison circuit.

FIG. 4(A) and FIG. 4(B) are illustrations of ons and offs of bypass switches.

FIG. 5 shows a diagram illustrating how a reference voltage is determined.

FIG. 6 shows a diagram illustrating that a hysteresis width is set to four stages.

FIG. 7 shows a second configuration example of the comparison circuit.

FIG. 8 shows a detailed configuration example of fourth to sixth resistance circuits.

FIG. 9(A) and FIG. 9(B) are illustrations of ons and offs of bypass switches.

FIG. 10 shows one example of a signal waveform of each of an input signal and a first and second output signal.

FIG. 11 shows one example of an integrated circuit device.

FIG. 12 shows an illustration of an operation of the integrated circuit device.

FIG. 13 shows an illustration of the operation of the integrated circuit device.

FIG. 14 shows one example of an electronic apparatus.

### MODE OF CARRYING OUT THE INVENTION

Hereafter, a detailed description will be given of a preferred embodiment of the invention. The embodiment, to be described hereafter, does not unduly limit the contents of the invention which are described in the claims, and not all of the configurations described in the embodiment are essential as solution means of the invention.

1. First Basic Configuration Example

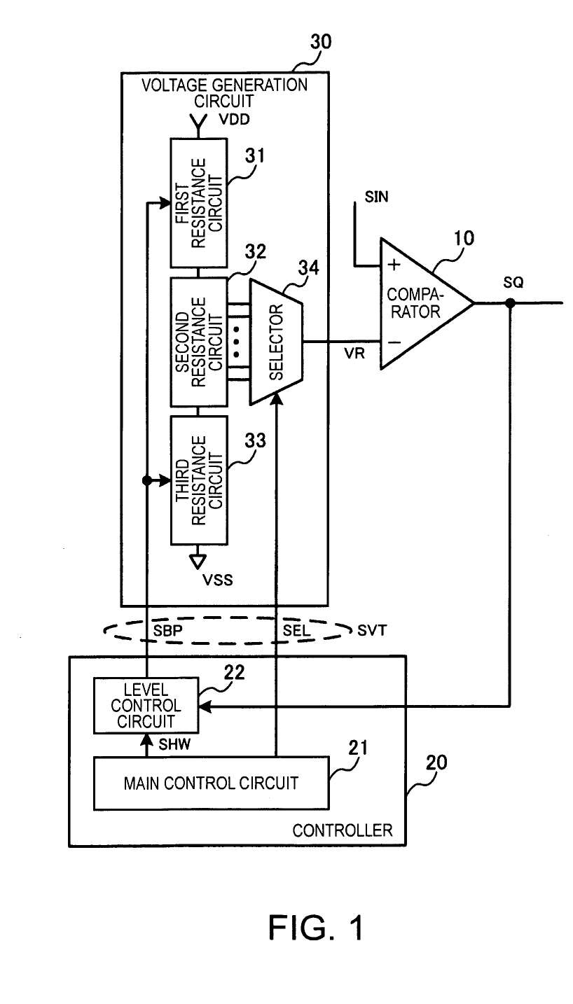

FIG. 1 shows a first basic configuration example of a comparison circuit of the embodiment. The comparison circuit of the embodiment includes a comparator 10, a controller 20, and a voltage generation circuit 30. An input signal SIN is input into a first input terminal (a non-inverting input terminal, a+input terminal) of the comparator 10, a reference voltage VR for comparison is input into a second input terminal (an inverting input terminal, a−input terminal) thereof, and the comparator outputs an output signal SQ. The controller 20 monitors the output signal SQ of the comparator 10. A threshold voltage control signal SVT from the controller is input into the voltage generation circuit 30, and the voltage generation circuit 30 outputs the reference voltage VR based on the threshold voltage control signal SVT.

The comparison circuit of the embodiment not being limited to the configuration of FIG. 1, various modification implementations, such as an omission of one portion of the components thereof, a replacement with other components, and an addition of other components, are possible.

The voltage generation circuit 30, when the voltage level of the output signal SQ of the comparator 10 is a first level (for example, a low voltage level, an L level), outputs as the reference voltage VR a first threshold voltage which is one of a high potential side (upper side) threshold voltage VTH and a low potential side (lower side) threshold voltage VTL which define a hysteresis width. In contrast, the voltage generation circuit 30, when the voltage level of the output signal SQ of the comparator 10 is a second level (for example, a high voltage level, an H level), outputs a second threshold voltage which is the other one of the high potential side threshold voltage VTH and low potential side threshold voltage VTL.

For example, the voltage generation circuit 30 outputs the high potential side threshold voltage VTH as the reference voltage VR when the output signal SQ of the comparator 10 is at the L level, and outputs the low potential side threshold voltage VTL as the reference voltage VR when the output signal SQ is at the H level. When the voltage value of the hysteresis width is taken to be VHW, VHW is given as VHW=VTH−VTL.

The voltage generation circuit 30 includes first to third resistance circuits 31, 32, and 33, and a selector 34. The first to third resistance circuits 31, 32, and are provided in series between a first power source node (a low potential side power source node) VSS and a second power source node (a high potential side power source node) VDD. For example, as shown in FIG. 1, one end of the first resistance circuit 31 is connected to the second power source node VDD, and the other end thereof is connected to one end of the second resistance circuit 32. Furthermore, the other end of the second resistance circuit 32 is connected to one end of the third resistance circuit 33, and the other end of the third resistance circuit 33 is connected to the first power source node VSS. That is, the second resistance circuit 32 is provided between the first resistance circuit 31 and third resistance circuit 33.

The resistance value of each of the first and third resistance circuits 31 and 33 is set based on the threshold voltage control signal SVT from the controller 20. Specifically, the resistance value is set by a plurality of bypass switches included in each of the first and third resistance circuits 31 and 33 being switched on and off by a bypass switch control signal SBP included in the threshold voltage control signal SVT. It is possible to change the hysteresis width VHW by changing the resistance value of each of the first and third resistance circuits 31 and 33, as will be described hereafter.

The selector 34, based on a selection signal SEL included in the threshold voltage control signal SVT from the controller 20, selects one voltage division node among a plurality of voltage division nodes of the second resistance circuit 32, and outputs the reference voltage VR. By this means, it is possible to set the reference value of a threshold voltage having the hysteresis width.

The controller 20 includes a main control circuit 21 and a level control circuit 22. The main control circuit outputs the selection signal SEL for selecting a voltage division node of the second resistance circuit 32, and a hysteresis width setting signal SHW for setting the hysteresis width. The level control circuit 22, based on the output signal SQ of the comparator 10, and on the hysteresis width setting signal SHW, outputs the bypass switch control signal SBP.

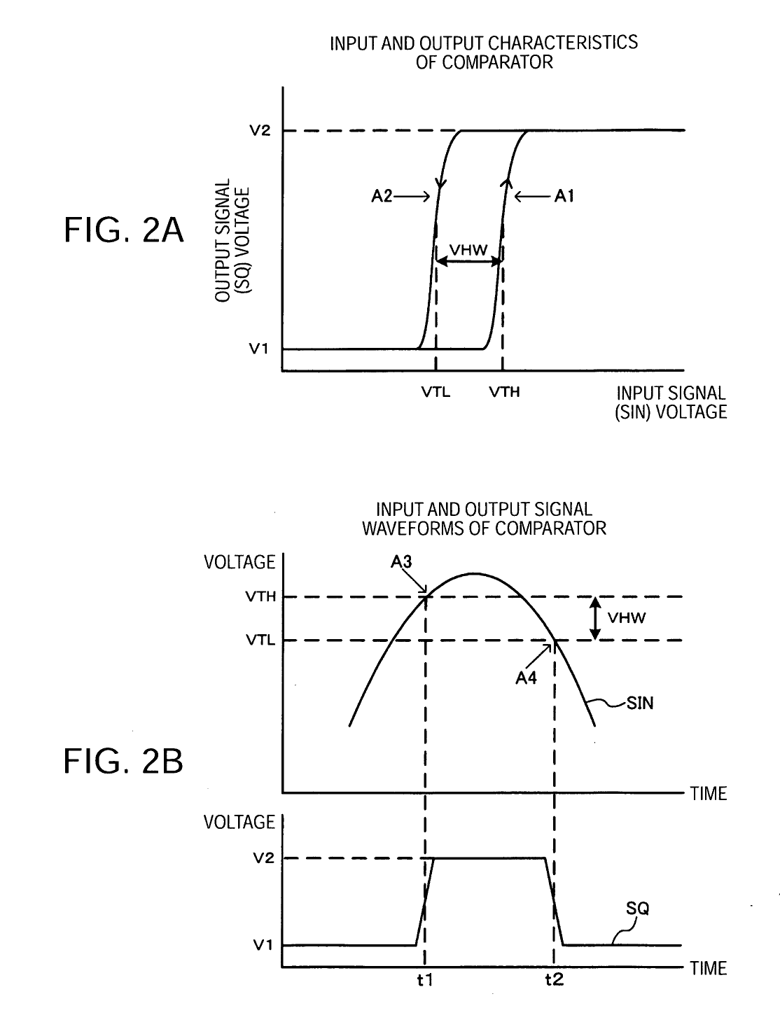

FIG. 2(A) and FIG. 2(B) are diagrams for illustrating an operation of the comparator 10. As one example, the diagrams illustrate cases in which the voltage generation circuit 30 outputs the high potential side threshold voltage VTH as the reference voltage VR when the output signal SQ of the comparator 10 is at the L level, and outputs the low potential side threshold voltage VTL as the reference voltage VR when the output signal SQ is at the H level. FIG. 2(A) shows the input and output characteristics of the comparator 10 in the heretofore described example. Hereafter, a description will be given calling the “high potential side” the “upper side”, and the “low potential side” the “lower side”.

As shown in FIG. 2(A), when the voltage level of the input signal SQ is sufficiently low, as the first level (L level) V1 is output as the output signal SQ, the reference voltage VR is set to the upper side threshold voltage VTH. On the voltage level of the input signal SQ rising gradually, and reaching the set reference voltage VR, that is, the upper side threshold voltage VTH, the output signal SQ makes a transition to the second level (H level) V2, as shown in A1 of FIG. 2(A). On the voltage level of the input signal SQ further rising, the output signal SQ holds the second level (H level) V2.

In contrast, when the voltage level of the input signal SQ is sufficiently high, as the second level (H level) V2 is output as the output signal SQ, the reference voltage VR is set to the lower side threshold voltage VTL. On the voltage level of the input signal SQ falling gradually, and reaching the set reference voltage VR, that is, the lower side threshold voltage VTL, the output signal SQ makes a transition to the first level (L level) V1, as shown in A2 of FIG. 2(A). On the voltage level of the input signal SQ further falling, the output signal SQ holds the first level (L level) V1.

As heretofore described, by setting the reference voltage VR to one of the upper side threshold voltage VTH and lower side threshold voltage VTL based on the voltage level of the output signal SQ of the comparator 10, it is possible to provide the comparator 10 with hysteresis characteristics. The hysteresis width VHW at this time is given as a difference (VTH−VTL) between the upper side threshold voltage VTH and the lower side threshold voltage VTL.

FIG. 2(B) shows one example of a signal waveform of each of the input signal SIN and output signal SQ of the comparator 10. A description will be given of a case in which, for example, the input signal SIN is a signal having its peak on the upper side, as shown in FIG. 2(B).

In an initial condition, as the first level (L level) is output as the output signal SQ, the reference voltage VR is set to the upper side threshold voltage VTH. As shown in A3 of FIG. 2(B), on the voltage level of the input signal SIN reaching the upper side threshold voltage VTH at a time t1, the output signal SQ makes a transition to the second level (H level) V2. By so doing, the reference voltage VR is set to the lower side threshold voltage VTL. Then, on the voltage level of the input signal SIN reaching the peak, starting to fall, and becoming equal to the lower side threshold voltage VTL at a time t2, as shown in A4 of FIG. 2(B), the output signal SQ makes a transition to the first level (L level) V1.

As heretofore described, it is possible, by using the comparison circuit of the embodiment, to determine whether or not the input signal level is higher than a predetermined threshold voltage. For example, in the examples shown in FIG. 2(A) and FIG. 2(B), the comparison circuit outputs the H level (second level) in a period in which the input signal level is higher than the predetermined threshold voltage, and the comparison circuit outputs the L level (first level) in a period in which the input signal level is lower than the predetermined threshold voltage.

It is also possible, using the comparator circuit of the embodiment, to determine whether or not the input signal level is lower than the predetermined threshold voltage. For example, in the circuit shown in FIG. 1, it is sufficient that the reference voltage VR for comparison is input into the first input terminal (non-inverting input terminal,+input terminal) of the comparator 10, and that the input signal SIN is input into the second input terminal (inverting input terminal,−input terminal). By so doing, the comparison circuit outputs the H level (second level) in the period in which the input signal level is lower than the predetermined threshold voltage, and the comparison circuit outputs the L level (first level) in the period in which the input signal level is higher than the predetermined threshold voltage.

With the comparison circuit of the embodiment, as it has the hysteresis characteristics, as heretofore described, it is possible, when the input signal includes noise, to prevent a phenomenon wherein the output signal level shuttles, in a very short period, between the L level and H level when the input signal level reaches a value close to the threshold voltage. By so doing, it is possible, when using the comparison circuit for a gain control of an amplification circuit, to prevent malfunction due to the noise.

Also, with the comparison circuit of the embodiment, as it is possible to provide the hysteresis characteristics without using a positive feedback, it is possible to prevent an effect of a feedback current on the preceding circuit.

Furthermore, with the comparison circuit of the embodiment, as it is possible to change the hysteresis width, it is possible to set an optimum hysteresis width in accordance with the input signal level, a noise level, or the like. By so doing, it is possible to realize a more stable gain control of the amplification circuit.

2. First Detailed Configuration Example

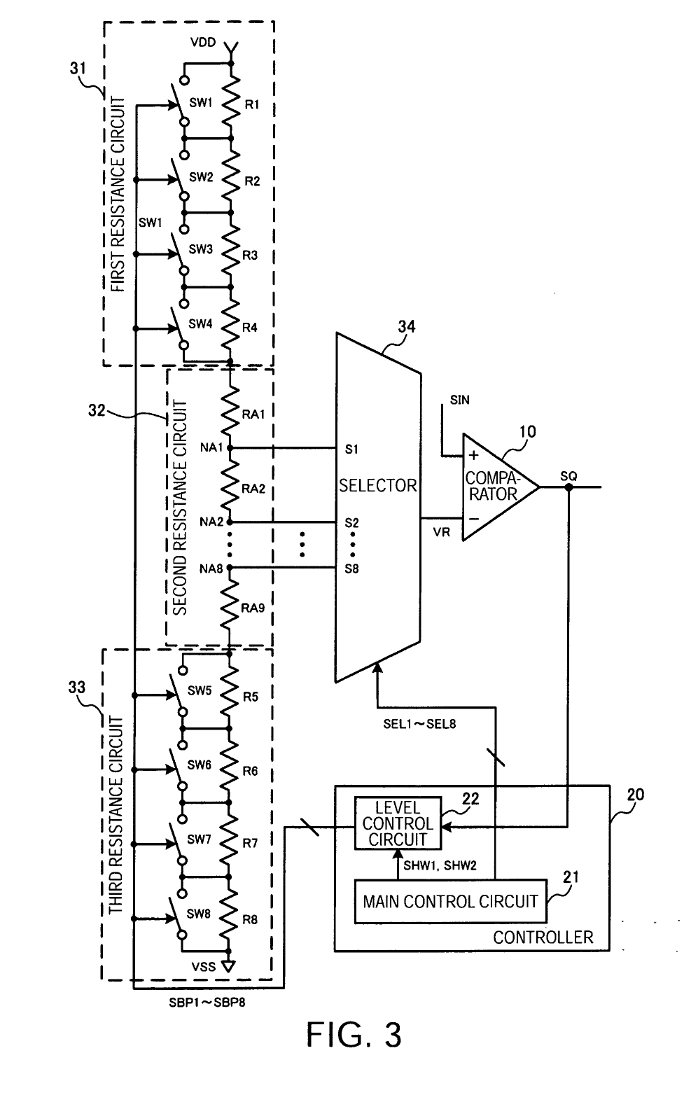

FIG. 3 shows a first detailed configuration example of the comparison circuit of the embodiment. In the configuration example, the first resistance circuit 31 includes first to fourth resistance elements R1 to R4 (in the broad sense, first to mth resistance elements, m is an integer of two or more), and first to fourth bypass switches SW1 to SW4 (in the broad sense, first to mth bypass switches) provided corresponding to the first to fourth resistance elements R1 to R4. Furthermore, the third resistance circuit 33 includes fifth to eighth resistance elements R5 to R8 (in the broad sense, m+1th to nth resistance elements, n is an integer wherein n≧+2), and fifth to eighth bypass switches SW5 to SW8 (in the broad sense, m+1th to nth bypass switches) provided corresponding to the fifth to eighth resistance elements R5 to R8. The first to fourth bypass switches SW1 to SW4 (in the broad sense, the first to mth bypass switches), and the fifth to eighth bypass switches SW5 to SW8 (in the broad sense, the m+1th to nth bypass switches), are on and off controlled by bypass switch control signals SBP1 to SBP8 (in the broad sense, the threshold voltage control signal). The above mentioned bypass switches can be configured using MOS transistors (transfer gates) or the like.

Also, in the detailed configuration example of FIG. 3, the second resistance circuit 32 including nine resistance elements RA1 to RA9 (in the broad sense, a plurality of resistance elements), voltage division nodes formed by these resistance elements are voltage division nodes NA1 to NA8 (in the broad sense, a plurality of voltage division nodes). The selector 34, based on selection signals SEL1 to SEL 8 (in the broad sense, the threshold voltage control signal), selects one voltage division node among the eight voltage division nodes NA1 to NA8 (in the broad sense, the plurality of voltage division nodes) of the second resistance circuit 32, and outputs the reference voltage VR.

The comparison circuit of the embodiment not being limited to the configuration of FIG. 3, various modification implementations, such as an omission of one portion of the components thereof, a replacement with other components, and an addition of other components, are possible.

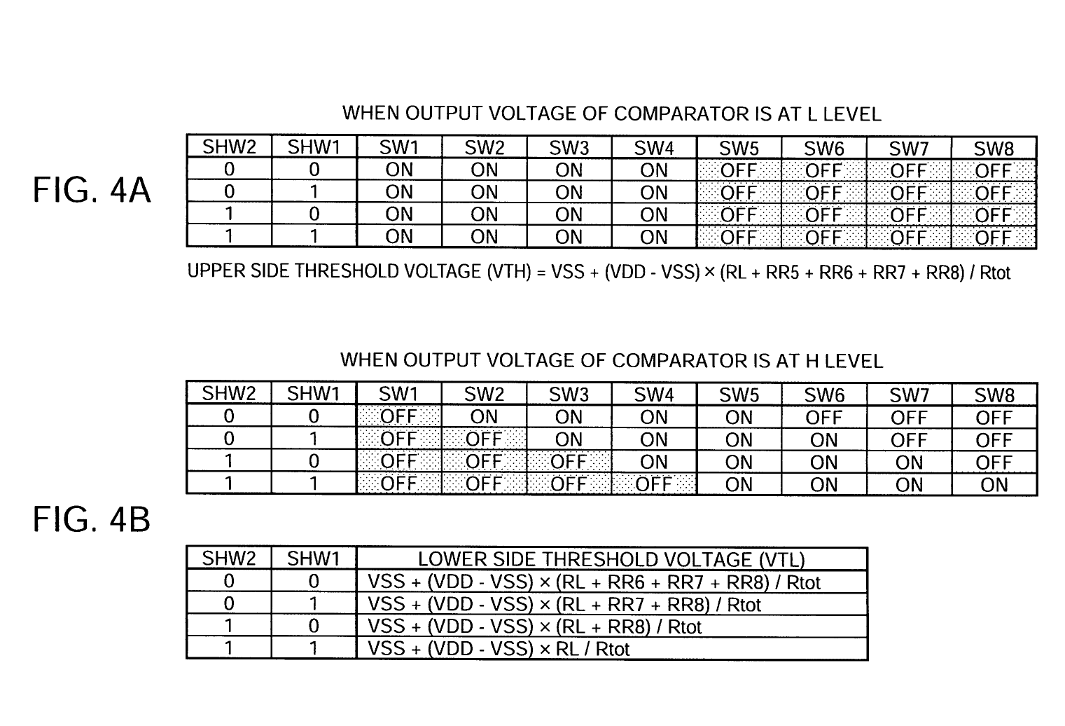

FIG. 4(A) and FIG. 4(B) are diagrams for illustrating how the first to eighth bypass switches SW1 to SW8 are turned on and off. FIG. 4(A) shows a case in which the voltage level of the output signal SQ of the comparator 10 is the L level, and FIG. 4(B) shows a case in which the voltage level of the output signal SQ is the H level.

As shown in FIG. 4(A), when the voltage level of the output signal SQ of the comparator 10 is the L level (in the broad sense, the first level), the first to fourth bypass switches SW1 to SW4 of the first resistance circuit 31 come into an on condition (a bypassed condition), and the fifth to eighth bypass switches SW5 to SW8 of the third resistance circuit 33 come into an off condition (a non-bypassed condition). When bypass switches are in the on condition, resistance elements connected in parallel to the bypass switches do not function electrically as resistors. That is, on all of the bypass switches SW1 to SW4 of the first resistance circuit 31 coming into the on condition, the resistance value of the first resistance circuit 31 is set to 0 ohm, and the resistance value of the third resistance circuit is set to the sum of the resistance values of the fifth to eighth resistance elements R5 to R8. An on resistance (resistance in the on condition) exists in an actual bypass switch, but it is possible to ignore the on resistance by making the resistance value of the on resistance sufficiently smaller than the resistance value of a resistance element.

In contrast, as shown in FIG. 4(B), when the voltage level of the output signal SQ of the comparator 10 is the H level (in the broad sense, the second level), at least one of the first to fourth bypass switches SW1 to SW4 of the first resistance circuit 31 comes into the off condition, and at least one of the fifth to eighth bypass switches SW5 to SW8 of the third resistance circuit comes into the on condition.

Specifically, each bypass switch is turned on and off in response to four-stage hysteresis widths set by a first and second bit SHW1 and SHW2 of the hysteresis width setting signal SHW. For example, when SHW1=0 and SHW2=0, SW1 and SW6 to SW8 come into the off condition, and the other bypass switches come into the on condition.

The resistance value of each of the first to fourth resistance elements R1 to R4 and fifth to eighth resistance elements R5 to R8 is set in such a way as to satisfy the following conditions. A first sum value which is the sum of the resistance values of the first to fourth resistance elements R1 to R4 is equal to a second sum value which is the sum of the resistance values of the fifth to eighth resistance elements R5 to R8. Furthermore, the first sum value is equal to a third sum value which is the sum of the resistance values of resistance elements, among the first to fourth resistance elements R1 to R4 and fifth to eighth resistance elements R5 to R8, which are non-bypassed when the voltage level of the output signal SQ of the comparator 10 is the H level (in the broad sense, the second level).

Specifically, it is sufficient to set the resistance value of each resistance element, for example, in the following way. When the resistance values of the first to eighth resistance elements R1 to R8 are taken to be RR1 to RR8, they are set in such a way that RR1=RR5, RR2=RR6, RR3=RR7, and RR4=RR8. By so doing, even when the voltage level of the output signal SQ of the comparator 10 is the L level (in the case of FIG. 4(A)), or even when it is the H level (in the case of FIG. 4(B)), and furthermore, of whichever level the hysteresis width setting may be, the sum of the resistance values of the non-bypassed resistance elements is constant.

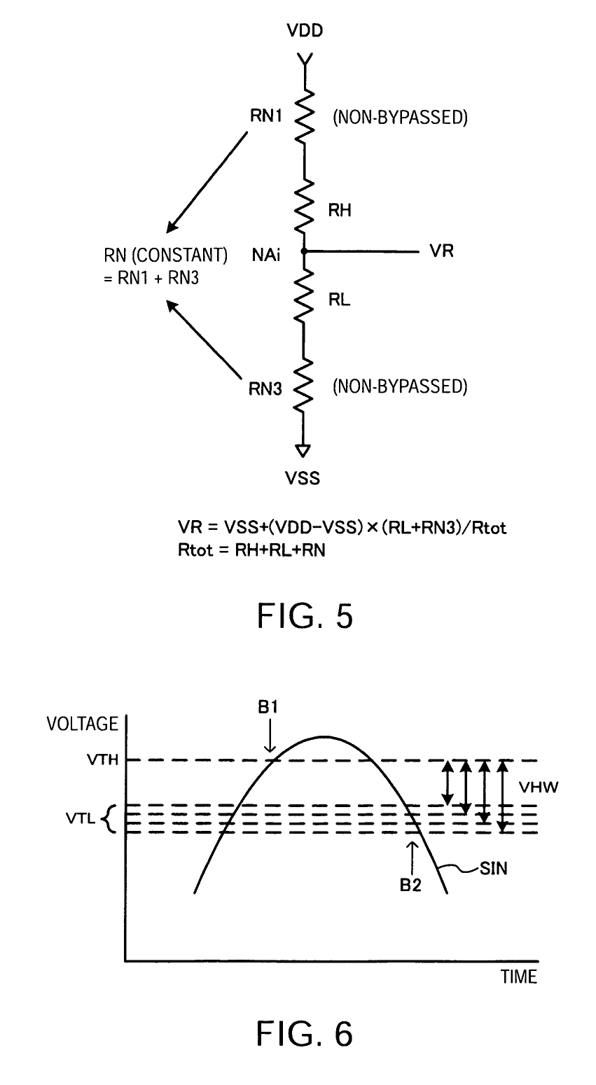

A description will be given, using FIG. 5, of how the reference voltage VR is determined. In FIG. 5, the selector 34 selects a voltage division node NAi (i is an integer wherein l≦i≦8) of the second resistance circuit 32. The sum of the resistance values of resistance elements, among the resistance elements RA1 to RA9 of the second resistance circuit 32, provided on the high potential side of the selected node NAi is taken to be RH, and the sum of the resistance values of resistance elements provided on the low potential side of the node NAi is taken to be RL. Also, the sum of the resistance values of non-bypassed resistance elements, among the resistance elements R1 to R4 of the first resistance circuit 31, is taken to be RN1, and the sum of the resistance values of non-bypassed resistance elements, among the resistance elements R5 to R8 of the third resistance circuit 33, is taken to be RN3. As the resistance values of all of the non-bypassed resistance elements are set in such a way that the sum of them is constant, as heretofore described, when the sum of the resistance values of the non-bypassed resistance elements is taken to be RN, RN(=RN1+RN3) is constant.

As shown in FIG. 5, the reference voltage VR is given as VR=VSS+(VDD−VSS)×(RL+RN3)/Rtot. Herein, Rtot, being all of the resistance values between the first power source node VSS and second power source node VDD, is given as Rtot=RH+RL+RN. RN3 can be changed by turning on and off the bypass switches SW1 to SW8.

For example, in the case of FIG. 4(A), as SW1 to SW4 are in the on condition, and SW5 to SW8 in the off condition, RN3=RR5+RR6+RR7+RR8. In this case, the reference voltage VR is the upper side threshold voltage VTH.

In contrast, in the case of FIG. 4(B), the reference voltage VR is the lower side threshold voltage VTL. In this case, it is possible, based on the first and second bits SHW1 and SHW2 of the hysteresis width setting signal SHW, to change RN3 to four stages. For example, when SHW1=0 and SHW2=0, RN3=RR6+RR7+RR8. Also, when SHW1=1 and SHW2=0, RN3=RR7+RR8. By so doing, it is possible to change the lower side threshold voltage VTL to four stages.

FIG. 6 shows that the lower side threshold voltage VTL is selectively set to four stages, as a result of which the hysteresis width VHW is selectively set to four stages. On the voltage level of the input signal SIN rising, and exceeding the upper side threshold voltage VTH, as shown in B1 of FIG. 6, the lower side threshold voltage VTL is set. At this time, as shown in B2 of FIG. 6, one of the four-stage VTL's is selected by the hysteresis width setting signal SHW.

As heretofore described, the reference voltage VR is given as VR=VSS+(VDD−VSS)×(RL+RN3)/Rtot. Herein, RL changes based on the selection signal SEL, and RN3 changes based on the hysteresis width setting signal SHW, but Rtot maintains a constant value. By so doing, even when a threshold voltage setting is changed, the hysteresis width is maintained constant, and furthermore, hysteresis width setting increments (steps) are also maintained constant.

In the configuration example of FIG. 3, even when the output signal SQ of the comparator 10 is at the L level, by turning on and off the bypass switches SW1 to SW8 based on the hysteresis width setting signal SHW, it is possible to gradually change the hysteresis width. By so doing, for example, in FIG. 6, it is also possible to selectively set the upper side threshold voltage VTH to four stages.

As heretofore described, according to the comparison circuit of the embodiment, as it is possible to gradually change the hysteresis width, it is possible to set the optimum hysteresis width in accordance with the input signal level, noise level, or the like. Furthermore, even when the threshold voltage setting is changed, the set hysteresis width is maintained constant. As a result, by using the comparison circuit of the embodiment for the gain control of the amplification circuit, it is possible to realize a stable gain control.

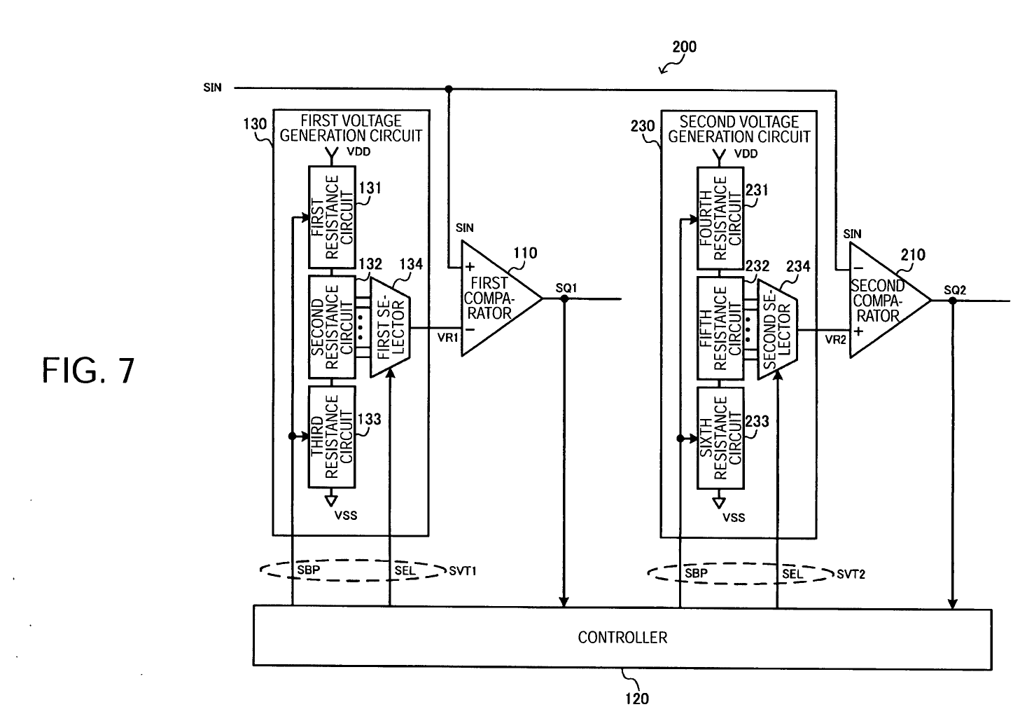

3. Second Configuration Example FIG. 7 shows a second configuration example of the comparison circuit of the embodiment. A comparison circuit 200 of the configuration example includes a first and second comparator 110 and 210, a controller 120, and a first and second voltage generation circuit 130 and 230. The comparison circuit of the embodiment not being limited to the configuration of FIG. 7, various modification implementations, such as an omission of one portion of the components thereof, a replacement with other components, an addition of other components, and the like, are possible.

An input signal SIN is input into a first input terminal (a non-inverting input terminal, a input terminal) of the first comparator 110, while a first reference voltage VR1 for comparison is input into a second input terminal (an inverting input terminal, a input terminal) thereof, and the first comparator 110 outputs a first output signal SQ1. A second reference voltage VR2 for comparison is input into a first input terminal (a non-inverting input terminal, a+input terminal) of the second comparator 210, while the input signal SIN is input into a second input terminal (an inverting input terminal, a−input terminal) thereof, and the second comparator 210 outputs a second output signal SQ2. The controller 120 monitors a first and second output signal SQ1 and SQ2 which are the output signals of the first and second comparators 110 and 210 respectively. A first and second threshold voltage control signal SVT1 and SVT2 from the controller 120 are input into the first and second voltage generation circuits 130 and 230.

The first voltage generation circuit 130 outputs as the first reference voltage VR1 a first high potential side (upper side) threshold voltage VT1H, which defines a first hysteresis width, when the voltage level of the first output signal SQ1 is a first level (a low voltage level, an L level), and outputs as the first reference voltage VR1 a first low potential side (lower side) threshold voltage VT1L, which defines the first hysteresis width, when the voltage level of the first output signal SQ1 is a second level (a high voltage level, an H level).

The second voltage generation circuit 230 outputs as the second reference voltage VR2 a second low potential side (lower side) threshold voltage VT2L, which defines a second hysteresis width, when the voltage level of the second output signal SQ2 is the first level (low voltage level, L level), and outputs as the second reference voltage VR2 a second high potential side (upper side) threshold voltage VT2H, which defines the second hysteresis width, when the voltage level of the second output signal SQ2 is the second level (high voltage level, H level).

The first voltage generation circuit 130 includes first to third resistance circuits 131, 132, and 133 provided in series between a first power source node (a low potential side power source node) VSS and a second power source node (a high potential side power source node) VDD, and a first selector 134. The resistance value of each of the first and third resistance circuits 131 and 133 is set based on the first threshold voltage control signal SVT1 from the controller 120.

The second voltage generation circuit 230 includes fourth to sixth resistance circuits 231, 232, and 233 provided in series between a first power source node (a low potential side power source node) VSS and a second power source node (a high potential side power source node) VDD, and a second selector 234. The resistance value of each of the fourth and sixth resistance circuits 231 and 233 is set based on the second threshold voltage control signal SVT2 from the controller 120.

It is possible to make the first to third resistance circuits 131, 132, and 133 identical in configuration to the first to third resistance circuits 31, 32, and 33 shown in FIG. 3. That is, the first resistance circuit 131 includes first to fourth resistance elements R1 to R4 (in the broad sense, first to mth resistance elements, m is an integer of two or more), and first to fourth bypass switches SW1 to SW4 (in the broad sense, first to mth bypass switches) provided corresponding to the first to fourth resistance elements R1 to R4. Furthermore, the third resistance circuit 133 includes fifth to eighth resistance elements R5 to R8 (in the broad sense, m+1th to nth resistance elements, n is an integer wherein n≧m+2), and fifth to eighth bypass switches SW5 to SW8 (in the broad sense, m+1th to nth bypass switches) provided corresponding to the fifth to eighth resistance elements R5 to R8. The first to fourth bypass switches SW1 to SW4 (in the broad sense, the first to mth bypass switches) and fifth to eighth bypass switches SW5 to SW8 (in the broad sense, the m+1th to nth bypass switches) are on and off controlled by bypass switch control signals SBP1 to SBP8 (in the broad sense, the first threshold voltage control signal).

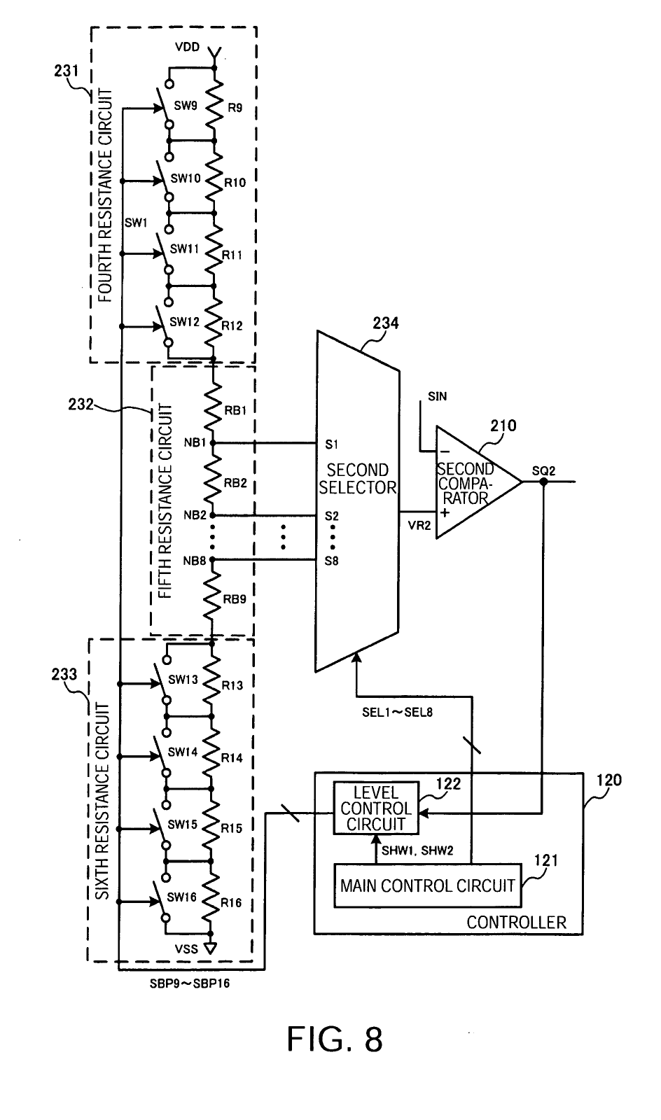

FIG. 8 shows a detailed configuration example of the fourth to sixth resistance circuits 231, 232, and 233. The fourth resistance circuit 231 includes ninth to twelfth resistance elements R9 to R12 (in the broad sense, n+1th to n+pth resistance elements, p is an integer of two or more), and ninth to twelfth bypass switches SW9 to SW12 (in the broad sense, n+1th to n+pth bypass switches) provided corresponding to the ninth to twelfth resistance elements R9 to R12. Furthermore, the sixth resistance circuit 233 includes thirteenth to sixteenth resistance elements R13 to R16 (in the broad sense, n+p+1th to n+qth resistance elements, q is an integer wherein q≧p+2), and thirteenth to sixteenth bypass switches SW13 to SW16 (in the broad sense, n+p+1th to n+qth bypass switches) provided corresponding to the thirteenth to sixteenth resistance elements R13 to R16. The ninth to twelfth bypass switches SW9 to SW12 and thirteenth to sixteenth bypass switches SW13 to SW16 are on and off controlled by bypass switch control signals SBP9 to SBP16 (in the broad sense, the second threshold voltage control signal).

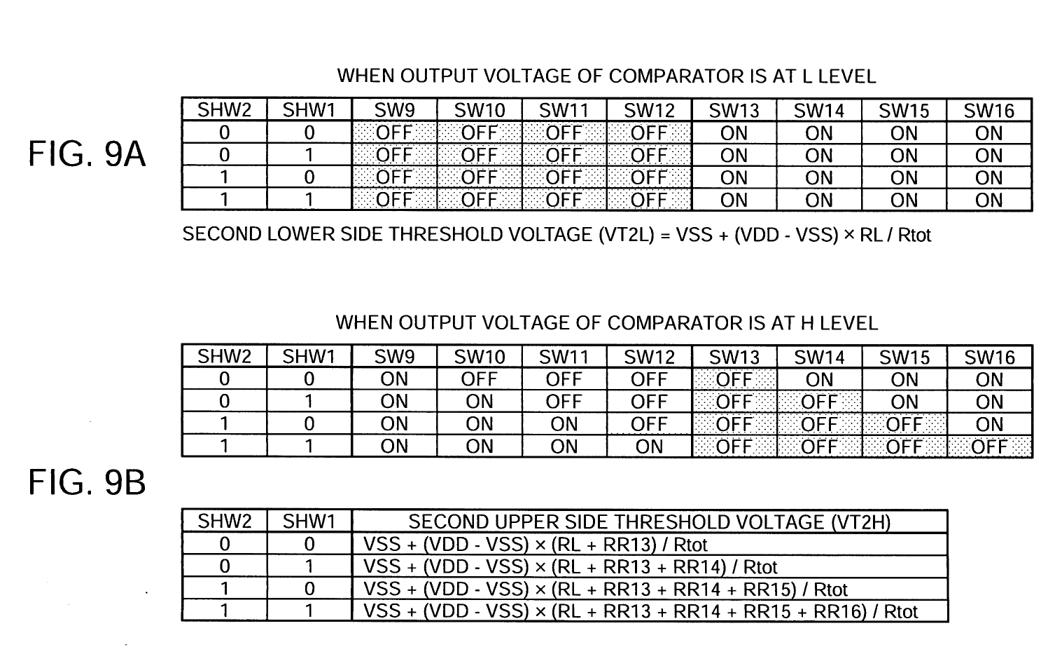

The first to eighth bypass switches SW1 to SW8 are on and off controlled, as shown in FIG. 4(A) and FIG. 4(B), outputting the first upper side threshold voltage VT1H and first lower side threshold voltage VT1L. In contrast, the ninth to sixteenth bypass switches SW9 to SW16 are on and off controlled, as shown in FIG. 9(A) and FIG. 9(B), outputting the second lower side threshold voltage VT2L and second upper side threshold voltage VT2H. It is possible to change the second upper side threshold voltage VT2H to four stages by means of the first and second bits SHW1 and SHW2 of the hysteresis width setting signal SHW. With regard to how VT2L and VT2H are determined, as it is the same way as that described in FIG. 5, a description is omitted here.

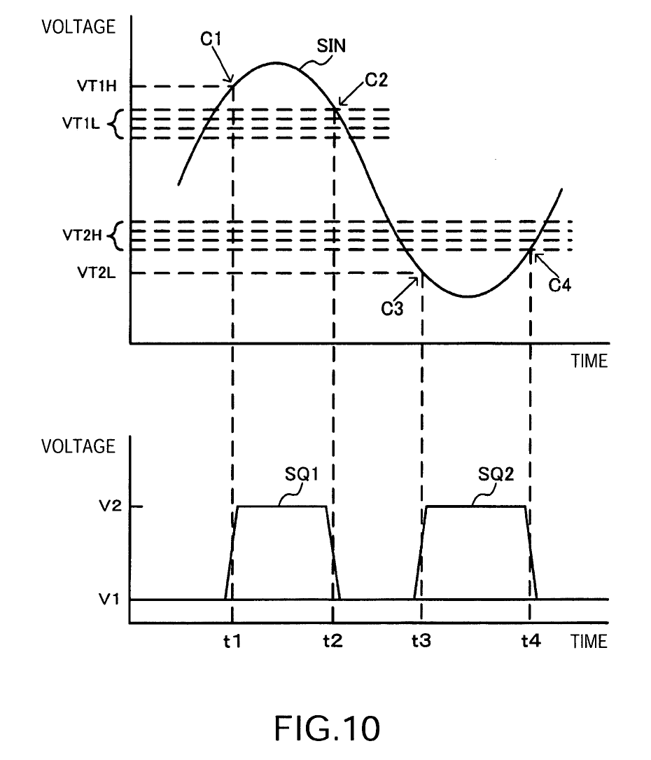

FIG. 10 shows one example of a signal waveform of each of the input signal SIN and first and second output signals SQ1 and SQ2 in the second configuration example of the comparison circuit of the embodiment.

In an initial condition, as the first level (L level) V1 is output as each of the first and second output signals SQ1 and SQ2, the first reference voltage VR1 is set to the first upper side threshold voltage VT1H, and the second reference voltage VR2 is set to the second lower side threshold voltage VT2L. As shown in C1 of FIG. 10, on the voltage level of the input signal SIN reaching the first upper side threshold voltage VT1H at a time t1, the first output signal SQ1 makes a transition to the second level (H level) V2. By so doing, the first reference voltage VR1 is set to the first lower side threshold voltage VT1L. Then, on the voltage level of the input signal SIN reaching the peak, starting to fall, and becoming equal to the first lower side threshold voltage VT1L at a time t2, as shown in C2 of FIG. 10, the first output signal SQ1 makes a transition to the first level (L level) V1.

On the voltage level of the input signal SIN falling further, and reaching the second lower side threshold voltage VT2L at a time t3, as shown in C3 of FIG. 10, the second output signal SQ2 makes a transition to the second level (H level) V2. By so doing, the second reference voltage VR2 is set to the second upper side threshold voltage VT2H. Then, on the voltage level of the input signal SIN starting to rise again, and reaching the second upper side threshold voltage VT2H at a time t4, as shown in C4 of FIG. 10, the second output signal SQ2 makes a transition to the first level (L level) V1.

As heretofore described, it is possible, by using the comparison circuit of the embodiment, to determine whether or not the input signal level is within two predetermined voltage ranges. For example, in the example shown in FIG. 10, it can be seen, in a period in which the first and second output signals SQ1 and SQ2 are both at the L level (first level), that the input signal level is within voltage ranges defined by the first and second threshold voltages.

Also, with the comparison circuit of the embodiment, as it has the hysteresis characteristics, as heretofore described, it is possible, when the input signal includes noise, to prevent a phenomenon wherein the output signal levels shuttle, in a very short period, between the L level and H level when the input signal level reaches values close to the threshold voltages. By so doing, it is possible, when using the comparison circuit for a gain control of an amplification circuit, to prevent malfunction due to the noise.

Also, with the comparison circuit of the embodiment, as it is possible to provide the hysteresis characteristics without using a positive feedback, it is possible to prevent an effect of a feedback current on the preceding circuit.

Furthermore, with the comparison circuit of the embodiment, as it is possible to gradually change the hysteresis width, it is possible to set an optimum hysteresis width in accordance with the input signal level, a noise level, or the like.

Furthermore, even when the threshold voltages settings are changed, the hysteresis width is maintained constant, and furthermore, the hysteresis width setting increments (steps) are also maintained constant. As a result, it is possible to realize a level determination circuit which can flexibly respond to the conditions of the input signal levels, noise level, or the like.

4. Integrated Circuit Device

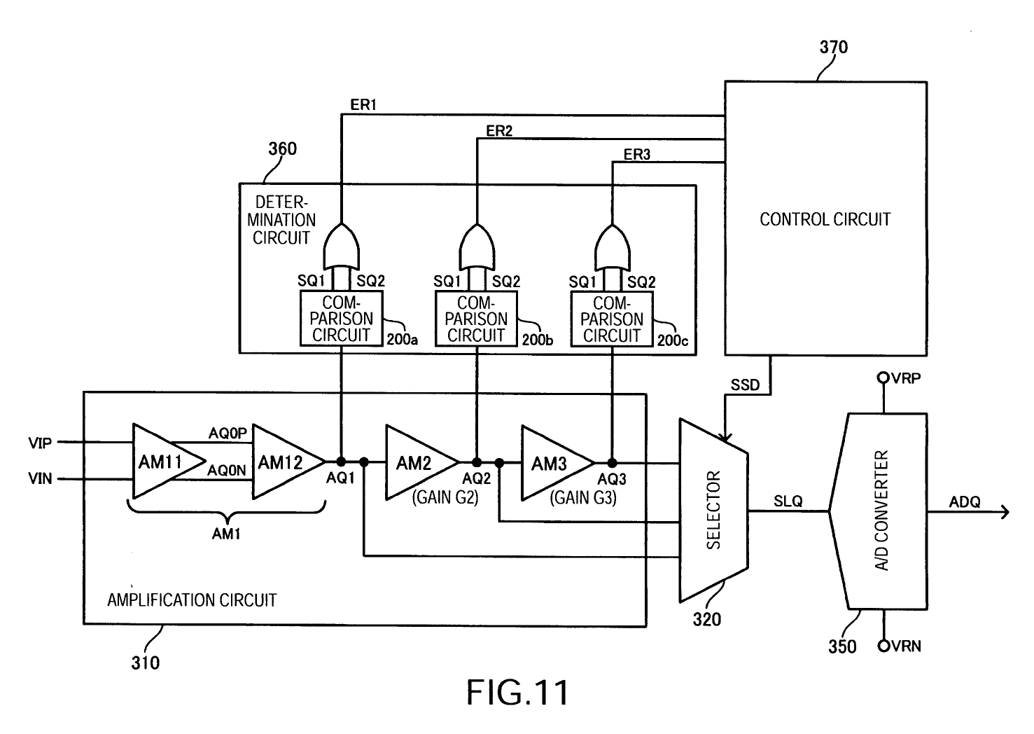

FIG. 11 shows one example of an integrated circuit device including the comparison circuit of the embodiment. The integrated circuit device of FIG. 11, being an A/D conversion circuit, includes an amplification circuit 310, a selector 320, an A/D converter 350, a determination circuit 360, and a control circuit 370. The amplification circuit 310 includes amplifiers AM1, AM2, and AM3, and the differential amplifier AM1 has amplifiers AM11 and AM12. The number of amplifiers, being optional, may be three to four or more.

The integrated circuit device of the embodiment not being limited to the configuration of FIG. 11, various modification implementations, such as an omission of one portion of the components thereof, a replacement with other components, an addition of other components, and the like, are possible.

The amplifier AM11, being a differential input and differential output amplifier, differentially amplifies differential input signals VIP and VIN. The amplifier AM12, being a differential input and single-end output amplifier, receives differential output signals AQ0P and AQ0N from the amplifier AM11, and outputs a single-ended signal AQ1. The first amplifier AM1 (differential amplifier) is configured by the amplifiers AM11 and AM12. Also, the following amplifiers AM2 and AM3, being single-end input and single-end output inverting amplifiers, output signals AQ2 and AQ3. The amplifiers AM2 and AM3 are configured in such a way that gains G2 and G3 thereof can be variably adjusted.

The determination circuit 360 includes comparison circuits 200a, 200b, and 200c of the embodiment. As the comparison circuits 200a, 200b, and 200c, it is possible to use the comparison circuit 200 shown in FIG. 7. The comparison circuits 200a, 200b, and 200c compare the voltages of the output signals AQ1, AQ2, and AQ3 of the amplifiers AM1 (AM11 and AM12), AM2, and AM3 with high potential side and low potential side determination voltages VCH and VCL. Then, the determination circuit 360 determines whether or not the voltages of the signals AQ1, AQ2, and AQ3 are within a determination voltage range of VCH to VCL. Then, when they are not within the determination voltage range, the determination circuit 360 activates error signals ER1, ER2, and ER3 (signals DRS) which indicate determination results. For example, when the output signals AQ1, AQ2, and AQ3 exceed the determination voltage range, the determination circuit 360 activates the signals ER1, ER2, and ER3 respectively.

Specifically, for example, when the voltage of the signal AQ1 is higher than the determination voltage VCH, the output signal SQ1 of the comparison circuit 200a is made the H level (activated). Also, when the voltage of the signal AQ1 is lower than the low potential side determination voltage VCL, the output signal SQ2 is made the H level (activated). Then, a logical sum (OR) of two output signals SQ1 and SQ2 is output as the error signal ER1 through an OR gate.

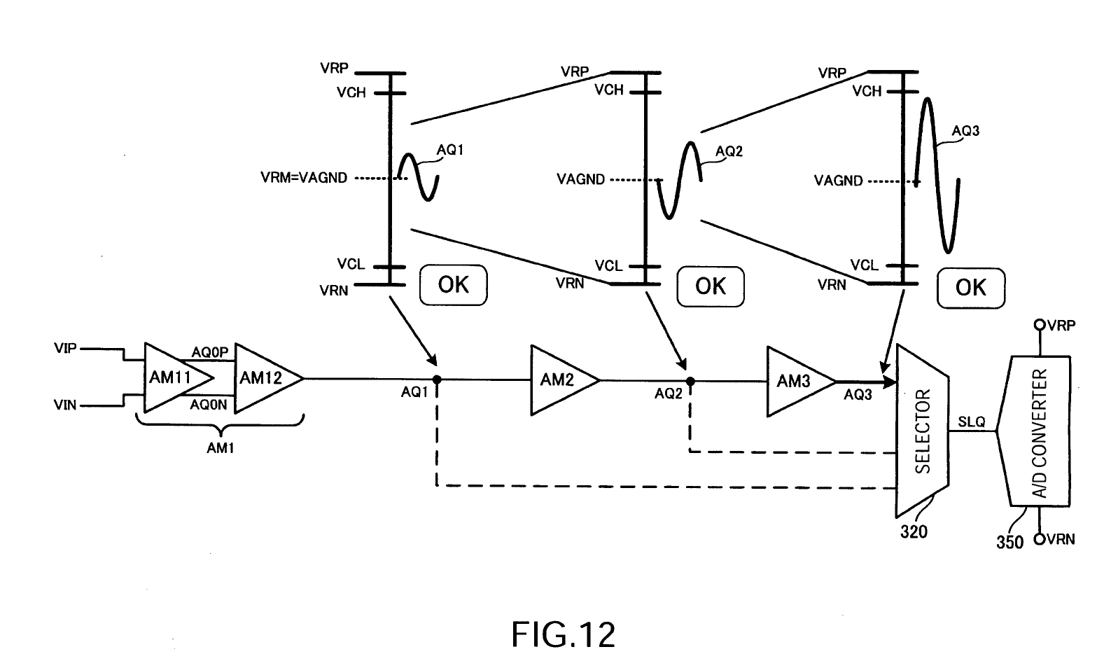

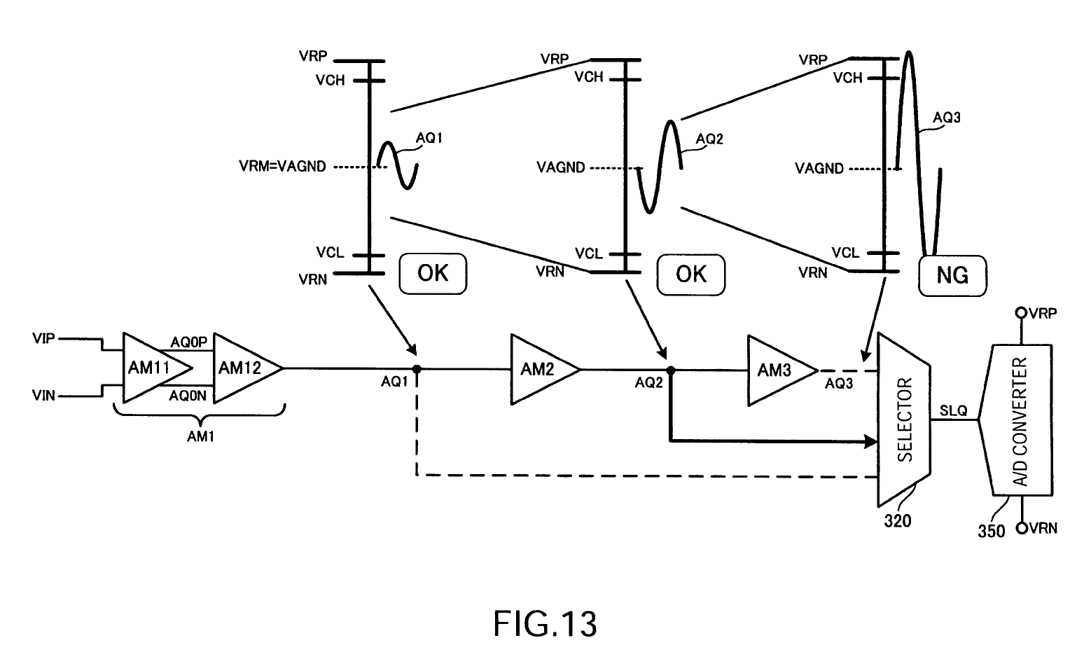

Next, a description will be given, using FIG. 12 and FIG. 13, of an operation of the integrated circuit device (A/D conversion circuit). In FIG. 12, the voltage of the output signal AQ1 of the amplifier AM1 is within the determination voltage range of VCH to VCL. Consequently, the error signal ER1 from the comparison circuit 200a of FIG. 11 is at the L level (non-activated). In the same way, in FIG. 12, the voltages of the output signals AQ2 and AQ3 of the amplifiers AM2 and AM3 are also within the determination voltage range of VCH to VCL. Consequently, the error signals ER2 and ER3 from the comparison circuits 200b and 200c are also at the L level (non-activated).

In this way, in FIG. 12, as the signals ER1, ER2, and ER3 are all at the L level, the control circuit 370 which has detected this outputs to the selector 320 a signal SSD which instructs it to select the output signal AQ3 of the amplifier AM3. By so doing, the selector 320 selects the signal AQ3, and the signal AQ3 is input into the A/D converter 350 as a selector output signal SLQ, and A/D converted. The signal AQ3 is greater in amplitude than the signals AQ2 and AQ1, and the high potential side and low potential side peak voltages thereof are close to reference voltages VRP and VRN of the A/D converter 350. Consequently, it is possible to increase an input amplitude VAT of the A/D converter 350, and it is possible to enhance a dynamic range DR=VAT/VLSB.

In FIG. 13, the output signals AQ1 and AQ2 of the amplifiers AM1 and AM2 are signals within the determination voltage range of VCH to VCL. In contrast, the output signal AQ3 of the amplifier AM3 is a signal outside the determination voltage range of VCH to VCL. Consequently, in this case, the error signals ER1, ER2, and ER3 from the comparison circuits 200a, 200b, and 200c are at the L, L, and H levels respectively, and a saturation of the amplifier AM3 is detected. By so doing, the control circuit 370 which has detected this outputs to the selector 320 a signal SSD which instructs it to select the output signal AQ2 of the amplifier AM2. By so doing, the selector 320 selects the signal AQ2, and the signal AQ2 is input into the A/D converter 350, and A/D converted. The signal AQ2 is greater in amplitude than the signal AQ1. Consequently, it is possible to increase the input amplitude of the A/D converter 350, and it is possible to improve the dynamic range. Also, it is possible to prevent a situation wherein the output signal AQ3 of the amplifier AM3 whose output has been saturated is input into the A/D converter 350, and an erroneous A/D conversion is carried out.

In this way, according to the integrated circuit device (A/D conversion circuit) including the comparison circuit of the embodiment, it is possible to improve the dynamic range, and furthermore, it is possible to prevent malfunction due to the output of the amplifier being saturated.

5. Electronic Apparatus

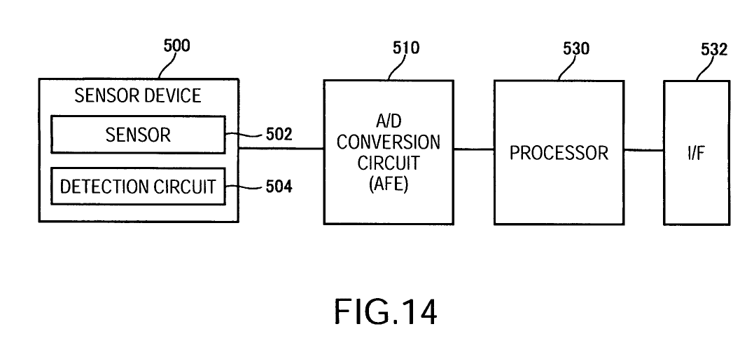

FIG. 14 shows one example of an electronic apparatus including the integrated circuit device (A/D conversion circuit). The electronic apparatus shown in FIG. 14 includes a sensor device 500, an A/D conversion circuit 510, which is an analog front end (AFE), a processor 530, and an interface (I/F) 532. The A/D conversion circuit 510 includes the comparison circuit of the embodiment.

With the electronic apparatus of FIG. 14, the sensor device 500 (a physical quantity transducer) detects various kinds of physical quantity (a force, an acceleration, mass, and the like). Then, it converts the physical quantities into currents (charges), voltages, or the like, and outputs them as detection signals. The sensor device 500 includes a sensor 502 and a detection circuit 504. A configuration may be such that it does not include the detection circuit 504.

The A/D conversion circuit 510 receives the detection signals from the sensor device 500, carries out an A/D conversion of the detection signals, and outputs digital data.

The processor 530 receives the digital data from the A/D conversion circuit 510, and carries out various kinds of process. The I/F 532 carries out a data forwarding, which complies with a standard such as, for example, USB or IEEE1394, with an external apparatus such as a PC (a personal computer).

According to the electronic apparatus of FIG. 14, it is possible to realize various electronic apparatus incorporating a smoke sensor, an optical sensor, a human presence sensor, a pressure sensor, a living organism sensor, a gyro sensor, or the like. Furthermore, it is possible to realize an electronic apparatus such as an evaluation apparatus (an evaluation board) used in a development, trial production, or the like, of the sensor device 500.

The embodiment has been described in detail as above, but it will be easily understandable to those skilled in the art that many modifications are possible without substantially departing from the new matters and advantages of the invention. Consequently, these kinds of modification example are all included in the scope of the invention. For example, terms described together with different terms having a more general meaning or the same meaning at least once in the specification or drawings can be replaced by the different terms in any place of the specification or drawings. Also, the configurations and operations of the comparison circuit, integrated circuit device, and electronic apparatus not being limited to those described in the embodiment either, various modification implementations are possible.

1. A comparison circuit, including:
a comparator into a first input terminal of which an input signal is input, and into a second input terminal of which a reference voltage for comparison is input;
a controller which monitors an output signal of the comparator; and
a voltage generation circuit into which a threshold voltage control signal from the controller is input, wherein
the voltage generation circuit, when the voltage level of the output signal of the comparator is a first level, outputs as the reference voltage a first threshold voltage which is one of a high potential side threshold voltage and a low potential side threshold voltage which define a hysteresis width, and
when the voltage level of the output signal of the comparator is a second level, outputs as the reference voltage a second threshold voltage which is the other one of the high potential side threshold voltage and the low potential side threshold voltage.

2. The comparison circuit according to claim 1, wherein
the voltage generation circuit includes a first resistance circuit to third resistance circuit provided in series between a first power source node and a second power source node, and
the resistance value of each of the first resistance circuit and third resistance circuit is set based on the threshold voltage control signal from the controller.

3. The comparison circuit according to claim 2, wherein
the first resistance circuit includes a first resistance element to mth resistance element (m is an integer of two or more) and a first bypass switch to mth bypass switch provided corresponding to the first resistance element to mth resistance element,
the third resistance circuit includes an m+1th resistance element to nth resistance element (n is an integer wherein n≧m+2) and an m+1th bypass switch to nth bypass switch provided corresponding to the m+1th resistance element to nth resistance element, and
the first bypass switch to mth bypass switch and m+1th bypass switch to nth bypass switch are on and off controlled by the threshold voltage control signal.

4. The comparison circuit according to claim 3, wherein
when the voltage level of the output signal of the comparator is the first level, the first bypass switch to mth bypass switch of the first resistance circuit come into an on condition, and the m+1th bypass switch to nth bypass switch of the third resistance circuit come into an off condition, and
when the voltage level of the output signal of the comparator is the second level, at least one of the first bypass switch to mth bypass switch of the first resistance circuit comes into the off condition, and at least one of the m+1th bypass switch to nth bypass switch of the third resistance circuit comes into the on condition.

5. The comparison circuit according to claim 4, wherein
a first sum value which is the sum of the resistance values of the first resistance element to mth resistance element is equal to a second sum value which is the sum of the resistance values of the m+1th resistance element to nth resistance element, and
the first sum value is equal to a third sum value which is the sum of the resistance values of resistance elements, among the first resistance element to mth resistance element and m+1th resistance element to nth resistance element, which are non-bypassed when the voltage level of the output signal of the comparator is the second level.

6. The comparison circuit according to claim 2, wherein
the voltage generation circuit includes a selector, and
the selector selects one voltage division node among a plurality of voltage division nodes of the second resistance circuit, and outputs the reference voltage.

7. A comparison circuit, including:
a first comparator into a first input terminal of which an input signal is input, and into a second input terminal of which a first reference voltage for comparison is input;
a second comparator into a first input terminal of which a second reference voltage for comparison is input, and into a second input terminal of which the input signal is input;
a controller which monitors a first output signal which is an output signal of the first comparator, and a second output signal which is an output signal of the second comparator;
a first voltage generation circuit into which a first threshold voltage control signal from the controller is input; and
a second voltage generation circuit into which a second threshold voltage control signal from the controller is input, wherein
the first voltage generation circuit, when the voltage level of the first output signal is a first level, outputs as the first reference voltage a first high potential side threshold voltage which defines a first hysteresis width, and when the voltage level of the first output signal is a second level, outputs as the first reference voltage a first low potential side threshold voltage which defines the first hysteresis width, and signal is a second level, outputs as the first reference voltage a first low potential side threshold voltage which defines the first hysteresis width, and
the second voltage generation circuit, when the voltage level of the second output signal is the first level, outputs as the second reference voltage a second low potential side threshold voltage which defines a second hysteresis width, and when the voltage level of the second output signal is the second level, outputs as the second reference voltage a second high potential side threshold voltage which defines the second hysteresis width.

8. The comparison circuit according to claim 7, wherein
the first voltage generation circuit includes a first resistance circuit to third resistance circuit provided in series between a first power source node and a second power source node,
the second voltage generation circuit includes a fourth resistance circuit to sixth resistance circuit provided in series between the first power source node and second power source node,
the resistance value of each of the first resistance circuit and third resistance circuit is set based on the first threshold voltage control signal from the controller, and
the resistance value of each of the fourth resistance circuit and sixth resistance circuit is set based on the second threshold voltage control signal from the controller.

9. The comparison circuit according to claim 8, wherein
the first resistance circuit includes a first resistance element to mth resistance element (m is an integer of two or more) and a first bypass switch to mth bypass switch provided corresponding to the first resistance element to mth resistance element,
the first bypass switch to mth bypass switch and m+1th bypass switch to nth bypass switch are on and off controlled by the first threshold voltage control signal, and that the fourth resistance circuit includes an n+1th resistance element to n+pth resistance element (p is an integer of two or more) and an n+1th bypass switch to n+pth bypass switch provided corresponding to the n+1th resistance element to n+pth resistance element,
the sixth resistance circuit includes an n+p+1th resistance element to n+qth resistance element (q is an integer wherein q≧+2) and an n+p+1th bypass switch to n+qth bypass switch provided corresponding to the n+p+1th resistance element to n+qth resistance element, and
the n+1th bypass switch to n+pth bypass switch and n+p+1th bypass switch to n+qth bypass switch are on and off controlled by the second threshold voltage control signal.

10. An integrated circuit device, including the comparison circuit according to claim 1.

11. An integrated circuit device, including the comparison circuit according to claim 7.

12. An electronic apparatus, including the integrated circuit device according to claim 10.

13. An electronic apparatus, including the integrated circuit device according to claim 11.
